(19) United States
(12) Patent Application Publication
(10) Pub. No.: US 2015/0162370 A1
(43) Pub. Date: Jun. 11, 2015

(54) SOLID STATE IMAGING DEVICE, ELECTRONIC APPARATUS, AND METHOD FOR MANUFACTURING SOLID STATE IMAGING DEVICE

(71) Applicant: Sony Corporation, Tokyo (JP)

(72) Inventor: Ryosuke Suenaga, Kumamoto (JP)

(21) Appl. No.: 14/559,713

(22) Filed: Dec. 3, 2014

(30) Foreign Application Priority Data
Dec. 10, 2013 (JP) 2013-254731

(51) Int. Cl. H01L 27/146; H04N 5/374

(52) U.S. Cl. CPC H01L 27/14627; H04N 5/374; H01L 27/14685

(57) ABSTRACT

A solid state imaging device includes a lens that is formed to correspond to a light receiving section which is made up of a photoelectric conversion device formed on a semiconductor substrate, an oxide film having a dry etching processing selection ratio that is formed on the lens, and a black resist layer that is formed by a dry etching processing, after being fully applied on the oxide film.

### CROSS REFERENCE TO RELATED APPLICATIONS

This application claims the benefit of Japanese Priority Patent Application JP 2013-254731 filed Dec. 10, 2013, the entire contents of which are incorporated herein by reference.

### BACKGROUND

The present disclosure relates to a solid state imaging device, and electronic apparatus, and a method for manufacturing a solid state imaging device, in particular, to a solid state imaging device, an electronic apparatus, and a method for manufacturing a solid state imaging device which are made so as to be capable of improving alignment accuracy at the time of forming a black resist layer.

As a method for preventing reflected light which is incident from a lens cap section, several technologies have been proposed. For example, in Japanese Unexamined Patent Application Publication No. 2008-016635, a technology that performs pattern formation of a light attenuation layer, is disclosed.

In Japanese Unexamined Patent Application Publication No. 2009-200418, a technology that leaves the light attenuation layer between filters by fully applying and etching a black resist on a color filter, is disclosed.

### SUMMARY

However, in the technology that performs the pattern formation of the light attenuation layer, in order to perform a exposure development handling of lithography, the resist is peeled off, or the alignment accuracy is fallen by shifting a position.

Moreover, in the technology that fully applies and etches the black resist on the color filter, when the etching is performed on a lens, there is concern that a lens shape is damaged.

The present disclosure is made in view of such circumstances, and is capable of improving alignment accuracy at the time of forming a black resist layer.

According to an embodiment of the present disclosure, there is provided a solid state imaging device including a lens that is formed to correspond to a light receiving section which is made up of a photoelectric conversion device formed on a semiconductor substrate, an oxide film having a dry etching processing selection ratio that is formed on the lens, and a black resist layer that is formed by a dry etching processing, after being fully applied on the oxide film.

In the solid state imaging device, the black resist layer may be formed by the dry etching processing so as to expose the lens.

In the solid state imaging device, the black resist layer may be formed so as to fill up between gaps among the lenses.

In the solid state imaging device, the lens may be a microlens.

In the solid state imaging device, the lens may be an inner lens.

The solid state imaging device may be a back face irradiation type.

The solid state imaging device may be a surface irradiation type.

According to another embodiment of the present disclosure, there is provided an electronic apparatus including a solid state imaging device having a lens that is formed to correspond to a light receiving section which is made up of a photoelectric conversion device formed on a semiconductor substrate, an oxide film having a dry etching processing selection ratio that is formed on the lens, and a black resist layer that is formed by a dry etching processing, after being fully applied on the oxide film, an optical system that makes incident light incident upon the solid state imaging device, and a signal handling circuit that handles an output signal which is output from the solid state imaging device.

According to still another embodiment of the present disclosure, there is provided a method for manufacturing a solid state imaging device, the method including causing a manufacturing apparatus to form a lens to correspond to a light receiving section which is made up of a photoelectric conversion device formed on a semiconductor substrate, form an oxide film having a dry etching processing selection ratio on the formed lens, and form a black resist layer by a dry etching processing, after fully applying the black resist layer on the formed oxide film.

In the embodiment of the present disclosure, the lens is formed to correspond to the light receiving section which is made up of the photoelectric conversion device formed on the semiconductor substrate, and the oxide film having the dry etching processing selection ratio, is formed on the formed lens. Therefore, after the black resist layer is fully applied on the formed oxide film, the black resist layer is formed by the dry etching processing.

According to the embodiments of the present disclosure, it is possible to form the black resist layer. Moreover, according to the embodiments of the present disclosure, it is possible to improve the alignment accuracy at the time of forming the black resist layer.

Furthermore, effects which are written in the present specification, are simply examples. The effects of the present disclosure are not limited to the effects which are written in the present specification, and there may be additional effects.

### BRIEF DESCRIPTION OF THE DRAWINGS

FIG. 1 is a block diagram illustrating a schematic configuration example of a solid state imaging device to which the present disclosure is applied;

FIG. 2 is a flowchart illustrating a formation handling of a black resist layer;

FIG. 3A, FIG. 3B, and FIG. 3C are diagrams illustrating a formation workflow of the black resist layer;

FIG. 4A, and FIG. 4B are diagrams illustrating the formation workflow of the black resist layer;

FIG. 5A, and FIG. 5B are diagrams illustrating an example of an effect; and

FIG. 6 is a block diagram illustrating a configuration example of an electronic apparatus to which the present disclosure is applied.

### DETAILED DESCRIPTION OF EMBODIMENTS

Hereinafter, forms (referred to as embodiments, hereinafter) for carrying out the present disclosure, will be described. Furthermore, the description is performed in the following order.

0. Schematic Configuration Example of Solid State Imaging Device

1. First Embodiment (Example of Solid State Imaging Device)

2. Second Embodiment (Example of Electronic Apparatus)

0. Schematic Configuration Example of Solid State Imaging Device

Schematic Configuration Example of Solid State Imaging Device

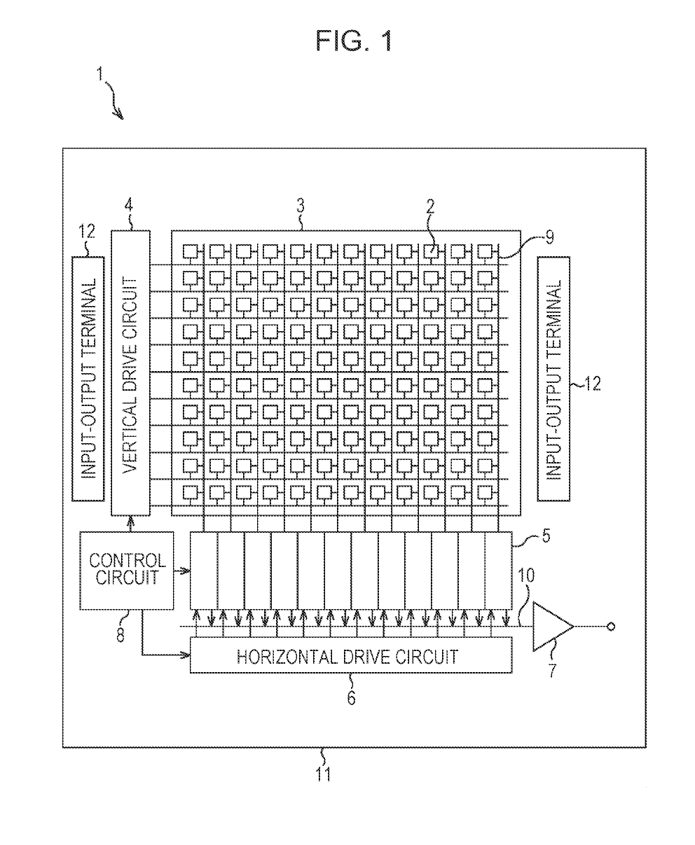

FIG. 1 shows a schematic configuration example of an example of a complementary metal oxide semiconductor (CMOS) solid state imaging device which is applied to each embodiment of the present disclosure.

As shown in FIG. 1, a solid state imaging device (device chip) 1, is configured to have a pixel domain (so-called imaging domain) 3 where pixels 2 including a plurality of photoelectric conversion devices, are regularly arranged in two dimensions on a semiconductor substrate 11 (for example, silicon substrate), and a peripheral circuit section.

The pixel 2 has the photoelectric conversion devices (for example, photodiodes), and a plurality of pixel transistors (so-called MOS transistors). For example, the plurality of pixel transistors can be configured with three transistors of a transfer transistor, a reset transistor, and an amplification transistor. Furthermore, the plurality of pixel transistors can be configured with four transistors by adding a selection transistor. Since an equivalent circuit of each pixel 2 (unit pixel) is the same as a general equivalent circuit, the detailed description will be omitted here.

Moreover, the pixel 2 can be assumed to have a pixel sharing structure. The pixel sharing structure is configured from the plurality of photodiodes, the plurality of transfer transistors, one floating diffusion which is shared, and other pixel transistors which are shared one by one.

The peripheral circuit section is configured from a vertical drive circuit 4, a column signal handling circuit 5, a horizontal drive circuit 6, an output circuit 7, and a control circuit 8.

The control circuit 8 receives data which commands an input clock, an operation mode or the like. Moreover, the control circuit 8 outputs the data such as inner information of the solid state imaging device 1. Specifically, based on a vertical synchronization signal, a horizontal synchronization signal, and a master clock, the control circuit 8 generates a clock signal or a control signal which becomes a reference of the operation of the vertical drive circuit 4, the column signal handling circuit 5, and the horizontal drive circuit 6. Therefore, the control circuit 8 inputs the signals to the vertical drive circuit 4, the column signal handling circuit 5, and the horizontal drive circuit 6.

The vertical drive circuit 4 is configured by, for example, a shift register, and selects a pixel drive wiring. The vertical drive circuit 4 supplies a pulse for driving the pixel 2, to the selected pixel drive wiring, and drives the pixel 2 by a row unit. Specifically, the vertical drive circuit 4 sequentially selects and scans each pixel 2 of the pixel domain 3 by the row unit, in a vertical direction, and supplies a pixel signal to the column signal handling circuit 5, based on a signal charge which is generated depending on a light receiving amount in the photoelectric conversion device of each pixel 2 through a vertical signal line 9.

The column signal handling circuit 5 is arranged, for example, per column of the pixel 2, and performs a signal handling such as noise removal onto the signal which is output from the pixels 2 of one row, per pixel column. Specifically, the column signal handling circuit 5 performs the signal handling such as correlated double sampling (CDS) for removing a peculiar fixed pattern noise of the pixel 2, signal amplification, and analog/digital (A/D) conversion. On an output stage of the column signal handling circuit 5, a horizontal selection switch (not shown) is arranged to be connected thereto between the column signal handling circuit 5 and a horizontal signal line 10.

The horizontal drive circuit 6 is configured by, for example, the shift register, and sequentially selects each of the column signal handling circuits 5 by sequentially outputting a horizontal scan pulse, and outputs the pixel signal to the horizontal signal line 10 from each of the column signal handling circuits 5.

The output circuit 7 outputs the signal by performing the signal handling with respect to the signal which is sequentially supplied through the horizontal signal line 10 from each of the column signal handling circuits 5. For example, the output circuit 7 may perform only buffering, or may perform black level adjustment, column scattering correction, and various digital signal handlings.

An output terminal 12 is arranged in order to exchange the signal with the outside.

### 1. First Embodiment

Formation Handling of Black Resist Layer

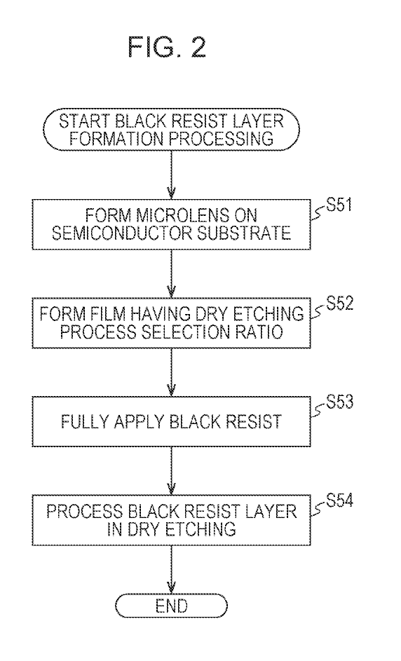

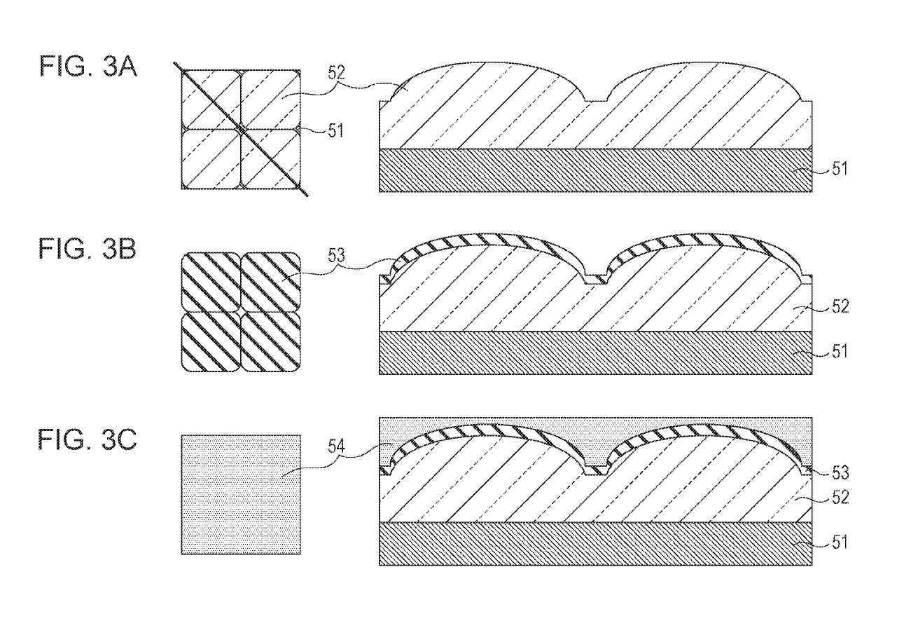

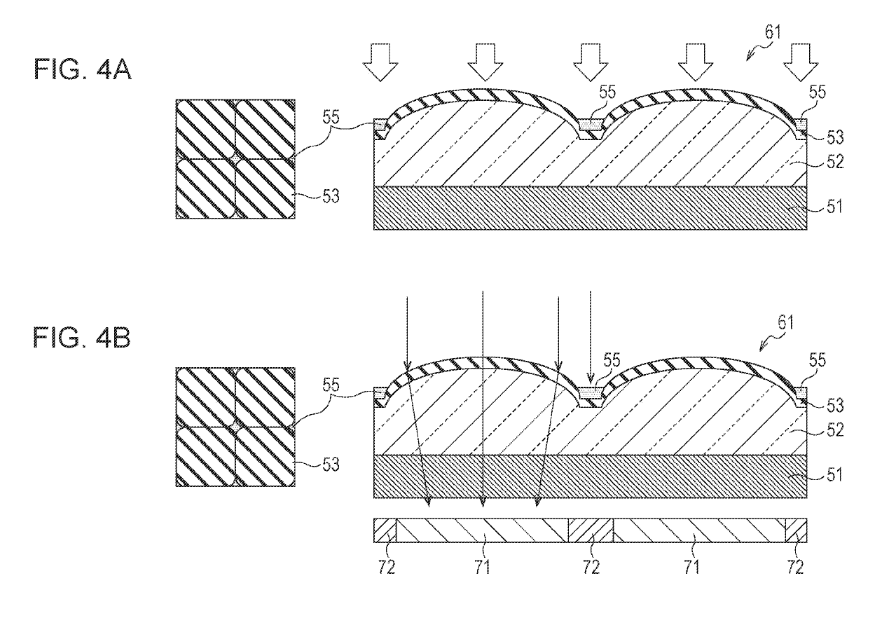

First, a formation handling of a black resist layer which is one handling in a solid state imaging device manufacturing handling of the present disclosure, will be described with reference to a flowchart of FIG. 2, and workflow charts of FIGS. 3A to 3C, FIG. 4A, and FIG. 4B.

Furthermore, the handling is a handling which is performed by a manufacturing apparatus to manufacture the solid state imaging device. Moreover, in the workflow charts of FIGS. 3A to 3C, FIG. 4A, and FIG. 4B, a plan view of the solid state imaging device is shown on a left side in the drawing, and a cross-sectional view when cut by a broken line (FIG. 3A) in the plan view, is shown on a right side in the drawing.

First, in a step S51, for example, as shown in FIG. 3A, the manufacturing apparatus forms the plurality of photoelectric conversion devices (not shown) on a semiconductor substrate 51, and in a light receiving section which is the photoelectric conversion device, forms a microlens 52 corresponding to each thereof.

In a step S52, as shown in FIG. 3B, with respect to the microlens 52 which is formed according to the step S51, the manufacturing apparatus forms an oxide film 53 having a dry etching processing selection ratio (high selection ratio).

In a step S53, as shown in FIG. 3C, after the oxide film 53 is formed according to the step S52, the manufacturing apparatus fully applies a black resist 54 on the semiconductor substrate 51.

In a step S54, as shown in FIG. 4A, after the black resist 54 is applied according to the step S53, the manufacturing apparatus uses the oxide film 53 as a stopper, and processes a black resist layer 55 in dry etching, so as to expose the microlens 52.

By the above workflow, so as to fill up between gaps among the microlenses 52, a solid state imaging device 61 where the black resist layer 55 is formed, is manufactured.

In the workflow, a patterning by lithography using a mask, is not necessary. Therefore, pattern peeling according to a black resist exposure phenomenon which may be generated when the patterning is performed by the lithography using the mask, is not generated.

Moreover, there is no superposition misalignment between the microlens 52 and the black resist layer 55 which is generated in order to perform the patterning by the lithography using the mask.

That is, in the present disclosure, as described above, the black resist layer 55 is formed in self-alignment with respect to a lens shape of the microlens 52. Therefore, it is possible to improve alignment accuracy.

Hereby, as shown in FIG. 4B, the light which is concentrated by the microlens 52, is received onto the light receiving section which is not shown in the drawing, through an opening section 71 that is arranged between wirings 72. Therefore, between the gaps among the microlenses 52, since the light from the adjacent microlens 52, is blocked by the black resist layer 55, it is possible to prevent deterioration of optical properties, and improve light-concentrating properties.

### Other Examples of Effects

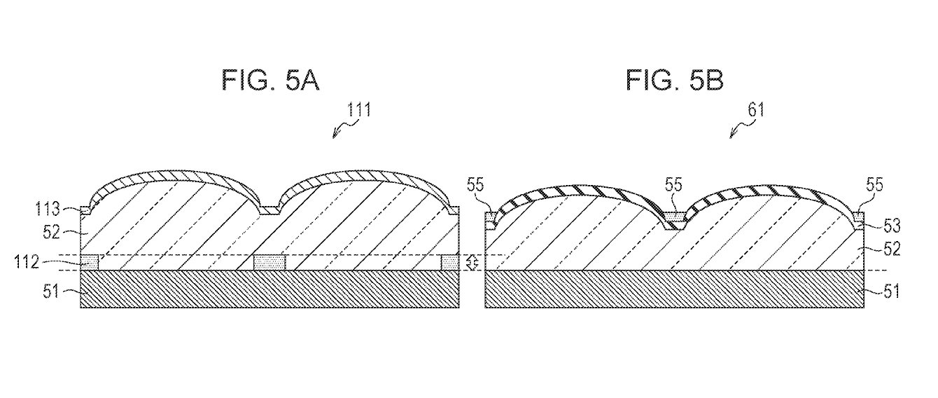

Next, with reference to FIG. 5A and FIG. 5B, other effects of the present disclosure will be described. FIG. 5A is a cross-sectional view of a solid state imaging device 111 when the patterning is performed by the lithography using the mask, and FIG. 5B is a cross-sectional view of a solid state imaging device 61 according to the present disclosure.

In the solid state imaging device 111, the photoelectric conversion device is formed on the semiconductor substrate 51, and after it is flattened, the black resist is fully applied. Thereafter, a black resist layer 112 is patterned according to the exposure phenomenon by the lithography using an exposure mask. After the phenomenon, the microlens 52 is formed on the black resist layer 112, and a low reflection film 113 is formed.

Therefore, as shown by an arrow in FIG. 5A, the solid state imaging device 61 of the present disclosure, can realize a low profile as film pressure of the black resist layer 112, in comparison with the solid state imaging device 111. Hereby, it is possible to increase freedom degrees relating to the light-concentrating.

Furthermore, in the above description, an example of the microlense is described, but the present disclosure can be applied to an inner lens. However, in a case of applying the present disclosure to the microlens which is positioned in an upper portion of the solid state imaging device, the performance is improved more than the case of applying the present disclosure to the inner lens.

Moreover, the present disclosure can be applied to a back face irradiation type solid state imaging device, and a surface irradiation type solid state imaging device.

Furthermore, the present disclosure is not limited to a black and white type solid state imaging device, and can be applied to a solid state imaging device where color filters are formed in a Bayer array shape, and a solid state imaging device where the array of each color filter is different.

In the above description, the configuration in which the present disclosure is applied to the CMOS solid state imaging device, is described, but the present disclosure may be applied to the solid state imaging device such as a charge coupled device (CCD) solid state imaging device.

Furthermore, the present disclosure is not limited to the application onto the solid state imaging device, and is applicable to an imaging unit. Here, the imaging unit is referred to as a camera system such as a digital still camera and a digital video camera, or an electronic apparatus having an imaging function such as a mobile phone. Additionally, a form of a module which is mounted on the electronic apparatus, that is, a camera module may be used as an imaging unit.

### 2. Second Embodiment

Configuration Example of Electronic Apparatus

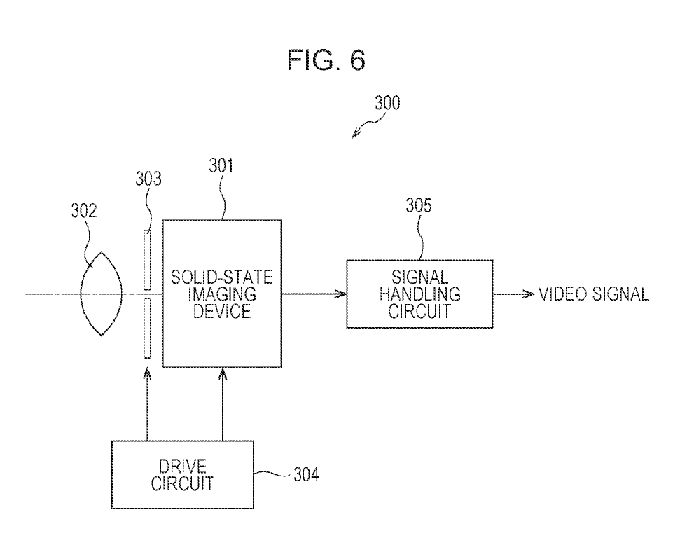

Here, a configuration example of an electronic apparatus according to a second embodiment of the present disclosure, will be described with reference to FIG. 6.

An electronic apparatus 300 which is shown in FIG. 6, includes a solid state imaging device (device chip) 301, an optical lens 302, a shutter unit 303, a drive circuit 304, and a signal handling circuit 305. As the solid state imaging device 301, the solid state imaging device 61 according to the first embodiment of the present disclosure described above, is arranged. Therefore, the position alignment accuracy of the black resist layer is increased. Hereby, the light-concentrating properties is improved.

The optical lens 302 forms an image on an imaging face of the solid state imaging device 301 with image light (incident light) from a subject. Hereby, the signal charge of a fixed period is accumulated within the solid state imaging device 301. The shutter unit 303 controls a light irradiation period and a light shielding period, with respect to the solid state imaging device 301.

The drive circuit 304 supplies a drive signal for controlling a signal transfer operation of the solid state imaging device 301, and a shutter operation of the shutter unit 303. By the drive signal (timing signal) which is supplied from the drive circuit 304, the solid state imaging device 301 performs the signal transfer. The signal handling circuit 305 performs various kinds of the signal handlings, with respect to the signal which is output from the solid state imaging device 301. A video signal into which the signal handling is performed, is stored in a storage medium such as a memory, and is output to a monitor.

Furthermore, in the present specification, the steps describing a series of handlings described above, include the handling which is performed in time series along the written order, needless to say, and the handling which is executed in parallel, or individually, even if not necessarily handled in time series.

Moreover, the embodiments of the present disclosure are not limited to the embodiments described above, and can be variously modified within the scope without departing the gist of the present disclosure.

Also, each step which is described in the flowcharts, can be executed by sharing with the plurality of units, in addition to the case of being executed with one unit.

Furthermore, when the plurality of handlings are included in one step, the plurality of handlings which are included in the step, can be executed by sharing with the plurality of units, in addition to the case of being executed with one unit.

Moreover, in the above description, dividing the configuration which is described as one unit (or handling section), the configuration may be made so as to be configured as the plurality of units (or handling sections). On the contrary, in the above description, gathering the configuration which is described as the plurality of units (or handling sections), the configuration may be made so as to be configured as one unit (or handling section). Additionally, needless to say, the configuration other than the configuration described above, may be added to the configuration of each unit (or each handling section). Furthermore, if the configuration as an entire system and the operations are substantially same, a portion of the configuration of one unit (or handling section) may be included in the configuration of other units (or other handling sections). That is, the present disclosure is not limited to the embodiments described above, and can be variously modified within the scope without departing the gist of the present disclosure.

In the above description, the suitable embodiments of the present disclosure are described in detail, with reference to the accompanying drawings, but the present disclosure is not limited to such examples. If being a person having the normal understanding in a field of the technology which belongs to the present disclosure, within a category of a technical idea which is written in the claims, it is clear that the person can perceive various modification examples and alteration examples, and those are naturally understood to belong to the technical scope of the present disclosure.

Furthermore, the present disclosure can employ the following configurations.

(1) A solid state imaging device including

a lens that is formed to correspond to a light receiving section which is made up of a photoelectric conversion device formed on a semiconductor substrate,

an oxide film having a dry etching processing selection ratio that is formed on the lens, and

a black resist layer that is formed by a dry etching processing, after being fully applied on the oxide film.

(2) The solid state imaging device according to the above (1),

in which the black resist layer is formed by the dry etching processing so as to expose the lens.

(3) The solid state imaging device according to the above (1) or (2),

in which the black resist layer is formed so as to fill up between gaps among the lenses.

(4) The solid state imaging device according to any one of the above (1) to (3),

in which the lens is a microlens.

(5) The solid state imaging device according to any one of the above (1) to (3),

in which the lens is an inner lens.

(6) The solid state imaging device according to any one of the above (1) to (5),

in which the device is a back face irradiation type.

(7) The solid state imaging device according to any one of the above (1) to (5),

in which the device is a surface irradiation type.

(8) An electronic apparatus including

a solid state imaging device having
a lens that is formed to correspond to a light receiving section which is made up of a photoelectric conversion device formed on a semiconductor substrate,
an oxide film having a dry etching processing selection ratio that is formed on the lens, and
a black resist layer that is formed by a dry etching processing, after being fully applied on the oxide film,

an optical system that makes incident light incident upon the solid state imaging device, and

a signal handling circuit that handles an output signal which is output from the solid state imaging device.

(9) A method for manufacturing a solid state imaging device, the method including

causing a manufacturing apparatus to
form a lens to correspond to a light receiving section which is made up of a photoelectric conversion device formed on a semiconductor substrate,
form an oxide film having a dry etching processing selection ratio on the formed lens, and
form a black resist layer by a dry etching processing, after fully applying the black resist layer on the formed oxide film.

It should be understood by those skilled in the art that various modifications, combinations, sub-combinations and alterations may occur depending on design requirements and other factors insofar as they are within the scope of the appended claims or the equivalents thereof.

What is claimed is:

1. A solid state imaging device comprising:
a lens that is formed to correspond to a light receiving section which is made up of a photoelectric conversion device formed on a semiconductor substrate;
an oxide film having a dry etching processing selection ratio that is formed on the lens; and
a black resist layer that is formed by a dry etching processing, after being fully applied on the oxide film.

2. The solid state imaging device according to claim 1,
wherein the black resist layer is formed by the dry etching processing so as to expose the lens.

3. The solid state imaging device according to claim 2,
wherein the black resist layer is formed so as to fill up between gaps among the lenses.

4. The solid state imaging device according to claim 1,
wherein the lens is a microlens.

5. The solid state imaging device according to claim 1,
wherein the lens is an inner lens.

6. The solid state imaging device according to claim 1,
wherein the device is a back face irradiation type.

7. The solid state imaging device according to claim 1,
wherein the device is a surface irradiation type.

8. An electronic apparatus comprising:
a solid state imaging device having
a lens that is formed to correspond to a light receiving section which is made up of a photoelectric conversion device formed on a semiconductor substrate,
an oxide film having a dry etching processing selection ratio that is formed on the lens, and
a black resist layer that is formed by a dry etching processing, after being fully applied on the oxide film;
an optical system that makes incident light incident upon the solid state imaging device; and
a signal handling circuit that handles an output signal which is output from the solid state imaging device.

9. A method for manufacturing a solid state imaging device, the method comprising:
causing a manufacturing apparatus to
form a lens to correspond to a light receiving section which is made up of a photoelectric conversion device formed on a semiconductor substrate,
form an oxide film having a dry etching processing selection ratio on the formed lens, and
form a black resist layer by a dry etching processing, after fully applying the black resist layer on the formed oxide film.
